(19) United States
(12) Patent Application Publication
(10) Pub. No.: US 2024/0079417 A1
(43) Pub. Date: Mar. 7, 2024

(54) DISPLAY DEVICE AND METHOD OF MANUFACTURING THE SAME

(71) Applicant: Samsung Display Co., LTD., Yongin-si (KR)

(72) Inventor: Chungi YOU, Yongin-si (KR)

(21) Appl. No.: 18/230,623

(22) Filed: Aug. 5, 2023

(30) Foreign Application Priority Data
Sep. 1, 2022 (KR) 10-2022-0111010

(51) Int. Cl. H01L 27/12

(52) U.S. Cl. CPC H01L 27/1244; H01L 27/1222; H01L 27/127

(57) ABSTRACT

A display device includes a substrate, a semiconductor layer disposed on the substrate, a gate insulating layer disposed on the semiconductor layer, a gate layer including a first layer disposed on the gate insulating layer and including a first metal, and a second layer disposed on the first layer and including a second metal, where a first through hole is defined through the second layer in a direction perpendicular to an upper surface of the first layer, and an interlayer insulating layer disposed on the gate layer.

This application claims priority to Korean Patent Application No. 10-2022-0111010, filed on Sep. 1, 2022, and all the benefits accruing therefrom under 35 U.S.C. § 119, the content of which in its entirety is herein incorporated by reference.

### BACKGROUND

### 1. Field

One or more embodiments relate to a display device and a method of manufacturing the display device, and more particularly, to a display device including a gate layer with a side surface having no protrusion portion, and a method of manufacturing the display device.

### 2. Description of the Related Art

Display devices are configured to receive information about images and display the images. A gate layer included in a display device may have a multilayer structure including a plurality of layers. When an etching process is applied to the gate layer during a manufacturing process of the display device, a protrusion portion protruding toward the outside of the gate layer may be formed on a side surface of the gate layer.

### SUMMARY

In a display device where an etching process is used to form a gate layer therein, a protrusion portion, which is formed on a side surface of the gate layer, has a high risk of making electrical contact with other conductive layers constituting a capacitor. In a case, where the capacitor is configured with the gate layer, the protrusion portion protruding toward the outside of the gate layer may be short-circuited with other conductive layers. Due to the short circuit, the voltage characteristics of the capacitor may substantially deteriorate.

One or more embodiments include a display device including a gate layer with a side surface having no protrusion portion, and a method of manufacturing the display device. However, this is merely an example, and the scope of the disclosure is not limited thereby.

According to one or more embodiments, a display device includes a substrate, a semiconductor layer disposed on the substrate, a gate insulating layer disposed on the semiconductor layer, a gate layer including a first layer disposed on the gate insulating layer and including a first metal, and a second layer disposed on the first layer and including a second metal, where a first through hole is defined through the second layer in a direction perpendicular to an upper surface of the first layer, and an interlayer insulating layer disposed on the gate layer.

In an embodiment, an acute angle between a first side surface of the first layer and an upper surface of the substrate may be less than an acute angle between a second side surface of the second layer and the upper surface of the substrate, where the first side surface and the second side surface may correspond to a same side surface of the gate layer.

In an embodiment, the first through hole may be defined through the interlayer insulating layer and the second layer together, and the display device may further include a first conductive layer disposed on the interlayer insulating layer and connected to the first layer through the first through hole.

In an embodiment, a groove may be defined in the first layer to correspond to the first through hole, and the first conductive layer may fill the groove.

In an embodiment, an angle between the first side surface and the second side surface may be less than about 180°.

In an embodiment, the first conductive layer may be connected to the semiconductor layer through a second through hole defined through the interlayer insulating layer and the gate insulating layer.

In an embodiment, the substrate may include a first area, in which the gate layer is located, and a second area, in which the semiconductor layer is located, among areas other than the first area. In such an embodiment, the first through hole may be located in the first area, and the second through hole may be located in the second area.

In an embodiment, the first metal may include titanium (Ti), and the second metal may include aluminum (Al).

In an embodiment, an etch rate of the first metal may be lower than an etch rate of the second metal under a same condition.

In an embodiment, the upper surface of the first layer may be in direct contact with the first conductive layer through the first through hole.

According to one or more embodiments, a method of manufacturing a display device includes providing a semiconductor layer on a substrate, providing a gate insulating layer on the semiconductor layer, providing a gate layer including a first layer disposed on the gate insulating layer and including a first metal, and a second layer disposed on the first layer and including a second metal, providing an interlayer insulating layer on the gate layer, and forming a first through hole through the interlayer insulating layer and the second layer, and a second through hole through the interlayer insulating layer and the gate insulating layer.

In an embodiment, the providing the gate layer may include forming the gate layer in a way such that an acute angle between a first side surface of the first layer and an upper surface of the substrate is less than an acute angle between a second side surface of the second layer and the upper surface of the substrate.

In an embodiment, the method may further include providing a first conductive layer on the interlayer insulating layer, to be connected to the first layer through the first through hole, and to be connected to the semiconductor layer through the second through hole.

In an embodiment, the forming the first through hole and the second through hole may include forming a groove corresponding to the first through hole in the first layer, and the providing the first conductive layer may include providing the first conductive layer to be connected to the first layer through the first through hole and the groove.

In an embodiment, the providing the first conductive layer may include providing the first conductive layer in a way such that an upper surface of the first layer is in direct contact with the first conductive layer through the first through hole.

In an embodiment, the providing the gate layer may include forming the first layer on the gate insulating layer, where the first layer includes the first metal, forming the second layer on the first layer, where the second layer includes the second metal, and patterning the first layer and the second layer in a preset shape.

In an embodiment, the forming the first through hole and the second through hole may include removing portions of the interlayer insulating layer corresponding to a position of the first through hole and a position of the second through hole, respectively, removing a portion of the second layer corresponding to the position of the first through hole, and removing a portion of the gate insulating layer corresponding to the position of the second through hole.

In an embodiment, an etch rate of the first metal may be lower than an etch rate of the second metal under a same condition.

In an embodiment, the first metal may include titanium (Ti), and the second metal may include aluminum (Al).

Other features of embodiments of the disclosure will become better understood through the detailed description, the claims, and the accompanying drawings.

### BRIEF DESCRIPTION OF THE DRAWINGS

The above and other features of certain embodiments of the disclosure will be more apparent from the following description taken in conjunction with the accompanying drawings, in which:

FIG. 1 is a schematic plan view of a display device according to an embodiment;

FIG. 2 is a schematic cross-sectional view of a display device according to an embodiment;

FIG. 3A is a schematic cross-sectional view of a display device before a through hole is formed therein, according to an embodiment;

FIG. 3B is an enlarged view of the encircled portion of FIG. 3A;

FIG. 4 is a schematic cross-sectional view of the display device of FIG. 3A when a through hole is formed therein;

FIG. 5 is a schematic cross-sectional view of the display device of FIG. 4 when a groove is formed therein;

FIG. 6 is a flowchart of a method of manufacturing a display device, according to an embodiment;

FIG. 7 is a schematic flowchart of a process of forming a gate layer in the method of FIG. 6;

FIG. 8 is a flowchart of a process of forming a through hole in the method of FIG. 6;

FIG. 9 is a flowchart of a process of forming a first conductive layer, which is added to the method of FIG. 6;

FIG. 10A is a schematic cross-sectional view of a display device according to a comparative example;

FIG. 10B is an enlarged view of the encircled portion of FIG. 10A;

FIG. 11 is a photograph showing a cross-section of a gate layer in the display device according to the comparative example;

FIG. 12 is a photograph showing a cross-section of a portion of the display device according to the comparative example; and

FIG. 13 is a photograph showing a cross-section of a gate layer in a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

It will be understood that, when a layer, film, region, or plate is referred to as being “on” another element, the layer, film, region, or plate may be “directly on” the other element, and intervening elements may be present therebetween. Also, sizes of elements in the drawings may be exaggerated or reduced for convenience of explanation. For example, because sizes and thicknesses of elements in the drawings are arbitrarily illustrated for convenience of explanation, the disclosure is not limited thereto.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

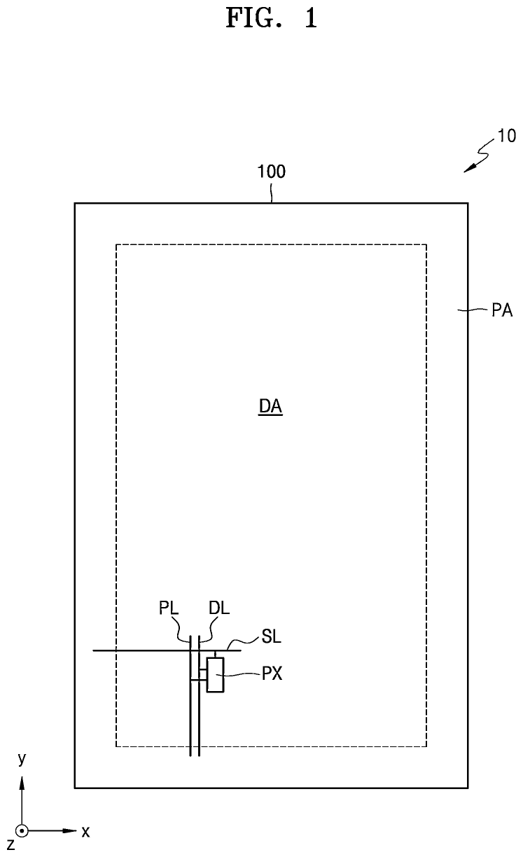

FIG. 1 is a schematic plan view of a display device according to an embodiment.

As illustrated in FIG. 1, the display device according to an embodiment may include a display panel 10. The disclosure may be applied to any type of display device as long as the display device includes the display panel 10. Examples of the display device may include various devices, such as smartphones, tablets, laptops, televisions, or billboards. The display device according to an embodiment includes thin-film transistors and a capacitor. The thin-film transistors and the capacitor may be implemented by conductive layers and insulating layers.

The display panel 10 includes a display area DA and a peripheral area PA outside the display area DA. FIG. 1 illustrates an embodiment where the display area DA has a rectangular shape. However, the disclosure is not limited thereto. The display area DA may have various shapes, for example, a circular shape, an elliptical shape, a polygonal shape, or a specific figure shape.

The display area DA allows an image to be displayed, and a plurality of pixels PX may be arranged in the display area DA. The pixels PX may each include a display element, such as an organic light-emitting diode (OLED). The pixels PX may emit, for example, red light, green light, or blue light. The pixel PX may be connected to a pixel circuit including a thin-film transistor (TFT), a storage capacitor, or the like. The pixel circuit may be connected to a scan line SL configured to transmit a scan signal to the pixel PX, a data line DL crossing the scan line SL and configured to transmit a data signal to the pixel PX, and a driving voltage line PL configured to supply a driving voltage to the pixel PX. The scan line SL may extend in the x direction, and the data line DL and the driving voltage line PL may extend in the y direction.

The pixel PX may be configured to emit light having a luminance corresponding to an electric signal output from the pixel circuit electrically connected thereto. The display area DA may enable a certain image to be displayed through light emitted from the pixel PX. The pixel PX as used herein may be defined as (or corresponding to) an emission area configured to emit one of red light, green light, and blue light, as described above.

The peripheral area PA is an area in which the pixels PX are not arranged, and may be an area in which an image is not displayed. Power supply lines for driving the pixels PX may be located in the peripheral area PA. Also, pads may be arranged in the peripheral area PA. A printed circuit board including a driving circuit or an integrated circuit (IC) element, such as a driver IC, may be arranged to be electrically connected to the pads.

For reference, in embodiments where the display panel 10 includes a substrate 100, it may be stated that the substrate 100 has the display area DA and the peripheral area PA. Detailed features of the substrate 100 will be described below.

In an embodiment, a plurality of transistors may be arranged in the display area DA. A first terminal of the transistor may be a source electrode or a drain electrode, and a second terminal of the transistor may be an electrode that is different from the first terminal, according to the type (N-type or P-type) of transistor and/or operating conditions. In an embodiment, for example, where the first terminal is a source electrode, the second terminal may be a drain electrode.

The transistors may include a driving transistor, a data write transistor, a compensation transistor, an initialization transistor, an emission control transistor, or the like. The driving transistor may be connected between the driving voltage line PL and the OLED, and the data write transistor may be connected to the data line DL and the driving transistor and may perform a switching operation of transmitting, to the pixel PX, the data signal transferred to the data line DL.

The compensation transistor may be configured to be turned on in response to the scan signal received through the scan line SL and compensate for a threshold voltage of the driving transistor by connecting the driving transistor to the OLED.

The initialization transistor may be configured to be turned on in response to the scan signal received through the scan line SL and initialize the gate electrode of the driving transistor by transmitting the initialization voltage to the gate electrode of the driving transistor. The scan line connected to the initialization transistor may be a separate scan line that is different from the scan line connected to the compensation transistor.

The emission control transistor may be configured to be turned on in response to an emission control signal received through an emission control line. As a result, a driving current may flow through the OLED.

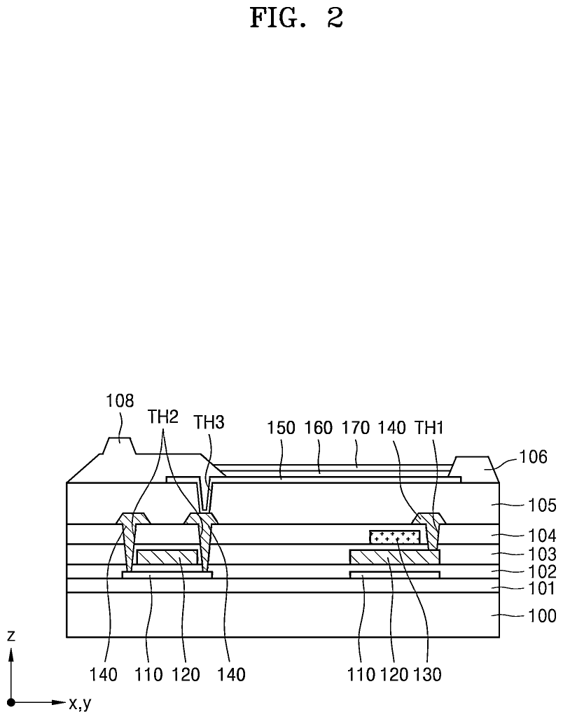

The OLED may include a pixel electrode (a first electrode or an anode) (see 150 in FIG. 2) and an opposite electrode (a second electrode or a cathode) (see 170 in FIG. 2). The opposite electrode 170 may be configured to receive a common voltage ELVSS. The OLED may be configured to display an image by emitting light according to the driving current received from the driving transistor.

Hereinafter, embodiments where the display device is an organic light-emitting display will be described in detail for convenience of description, but the display device according to embodiments of the disclosure is not limited thereto. In an alternative embodiment, the display device may include an inorganic light-emitting display (or an inorganic electroluminescence (EL) display), a quantum dot light-emitting display, or the like. In an embodiment, for example, an emission layer of a display element included in the display device may include an organic material or an inorganic material. Also, the display device may include an emission layer and quantum dots located on a path of light emitted from the emission layer.

FIG. 2 is a schematic cross-sectional view of a display device according to an embodiment.

As illustrated in FIG. 2, the display device according to an embodiment may include a substrate 100, and a semiconductor layer 110, a gate insulating layer 102, a gate layer 120 and an interlayer insulating layer 103, which are disposed on the substrate 100. Also, the display device according to an embodiment may further include a first insulating layer 104 and a first conductive layer 130. In addition, the display device according to an embodiment may further include a buffer layer 101, a second conductive layer 140, a second insulating layer 105, a pixel electrode 150, a pixel defining layer 106, an intermediate layer 160, and an opposite electrode 170.

As described above, the substrate 100 may include areas corresponding to the display area DA and the peripheral area PA outside the display area DA. The substrate 100 may include various flexible or bendable materials. In an embodiment, for example, the substrate 100 may include glass, metal, or polymer resin.

The buffer layer 101 may be disposed on the substrate 100. The buffer layer 101 may act as a barrier layer and/or a blocking layer that prevents impurity ions from diffusing, prevents infiltration of moisture or ambient air, and planarizes the surface of the substrate 100. The buffer layer 101 may include silicon oxide, silicon nitride, or silicon oxynitride. Also, the buffer layer 101 may control the rate of heat supply during a crystallization process for forming the semiconductor layer 110 so that the semiconductor layer 110 is uniformly crystallized.

The semiconductor layer 110 may be disposed on the buffer layer 101. The semiconductor layer 110 may include polysilicon. The semiconductor layer 110 may include a channel region 113 not doped with impurities, and a source region 111 and a drain region 112 respectively formed by doping both sides of the channel region 113 with impurities. The impurities may vary depending on the type of TFT, and may be an N-type impurity or a P-type impurity.

The gate insulating layer 102 may be disposed on the semiconductor layer 110. The gate insulating layer 102 may secure insulation between the semiconductor layer 110 and the gate layer 120. The gate insulating layer 102 may include an inorganic material, such as silicon oxide, silicon nitride, and/or silicon oxynitride, and may be between the semiconductor layer 110 and the gate layer 120. Also, the gate insulating layer 102 may have a shape corresponding to the entire surface of the substrate 100, and may have a structure in which contact holes are defined in preset portions thereof. The gate insulating layer 102 including the inorganic material may be formed by chemical vapor deposition (CVD) or atomic layer deposition (ALD). Such a features of the gate insulating layer 102 may be equally applied to embodiments and modifications to be described below.

The gate layer 120 may be disposed on the gate insulating layer 102. The gate layer 120 may be disposed at a position vertically overlapping the semiconductor layer 110, and may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), titanium (Ti), tungsten (W), and copper (Cu). Detailed features of the gate layer 120 will be described below.

The interlayer insulating layer 103 may be disposed on the gate layer 120. The interlayer insulating layer 103 may cover the gate layer 120. The interlayer insulating layer 103 may include an inorganic material. In an embodiment, for example, the interlayer insulating layer 103 may include a metal oxide or a metal nitride. In an embodiment, for example, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂). In some embodiments, the interlayer insulating layer 103 may have a dual structure of SiOₓ/SiN_{y} or SiNₓ/SiO_{y}.

The first conductive layer 130 may be disposed on the interlayer insulating layer 103. The first conductive layer 130 may act as another gate layer. Also, in an embodiment, the first conductive layer 130 may overlap the gate layer 120 with the interlayer insulating layer 103 therebetween to thereby function as a capacitor for display driving.

The first conductive layer 130 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), molybdenum (Mo), titanium (Ti), tungsten (W), and copper (Cu). In an embodiment, for example, the first conductive layer 130 may include a Ti layer, an Al layer, and/or a Cu layer.

The first insulating layer 104 may be disposed on the first conductive layer 130. The first insulating layer 104 may be an organic insulating layer acting as a planarization layer because the first insulating layer 104 covers the upper portion of the first conductive layer 130 and has a substantially flat upper surface. The first insulating layer 104 may include, for example, an organic material, such as acryl, benzocyclobutene (BCB), or hexamethyldisiloxane (HMDSO). The first insulating layer 104 may be variously modified. In an embodiment, for example, the first insulating layer 104 may be defined by a single layer or multi-layers. Detailed features of the first conductive layer 130 will be described below.

The second conductive layer 140 may be disposed on the first insulating layer 104. Also, the second conductive layer 140 may act as a wiring layer for data or power transmission. The second conductive layer 140 may include the same layer structure as that of the first conductive layer 130. The second conductive layer 140 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), molybdenum (Mo), titanium (Ti), tungsten (W), and copper (Cu). In an embodiment, for example, the second conductive layer 140 may include a Ti layer, an Al layer, and/or a Cu layer.

The second insulating layer 105 may be disposed on the second conductive layer 140. The second insulating layer 105 may have a same layer structure as that of the first insulating layer 104. The second insulating layer 105 may be an organic insulating layer acting as a planarization layer because the second insulating layer 105 covers the upper portion of the second conductive layer 140 and has a substantially flat upper surface. The second insulating layer 105 may include, for example, an organic material, such as acryl, BCB, or HMDSO. The second insulating layer 105 may be variously modified. In an embodiment, for example, the second insulating layer 105 may be defined by a single layer or multi-layers.

The pixel electrode 150 may be disposed on the second insulating layer 105. The pixel electrode 150 may be connected to the first conductive layer 130 or the second conductive layer 140 through a contact hole defined in the second insulating layer 105. A display element may be disposed on the pixel electrode 150. An OLED may be used as the display element. That is, the OLED may be disposed on, for example, the pixel electrode 150. The pixel electrode 150 may include a transmissive conductive layer including a transmissive conductive oxide, such as indium tin oxide (ITO), In₂O₃, or indium zinc oxide (IZO), and a reflective layer including a metal, such as Al or Ag. In an embodiment, for example, the pixel electrode 150 may have a three-layer structure of ITO/Ag/ITO.

The pixel defining layer 106 may be disposed on the second insulating layer 105 and may be disposed to cover the edge of the pixel electrode 150. In an embodiment, the pixel defining layer 106 may cover the edge of the pixel electrode 150. The pixel defining layer 106 may have an opening corresponding to a pixel. The opening may be defined or formed through the pixel defining layer 106 to expose at least a central portion of the pixel electrode 150.

The pixel defining layer 106 may include, for example, an organic material, such as polyimide or HMDSO. In an embodiment, a spacer 108 may be disposed on the pixel defining layer 106.

The intermediate layer 160 and the opposite electrode 170 may be disposed on the opening. The intermediate layer 160 may include a low molecular weight material or a high molecular weight material. In an embodiment where the intermediate layer 160 includes a low molecular weight material, the intermediate layer 160 may include a hole injection layer (HIL), a hole transport layer (HTL), an emission layer (EML), an electron transport layer (ETL), and/or an electron injection layer (EIL). In an embodiment where the intermediate layer 160 includes a high molecular weight material, the intermediate layer 160 may have a structure including an HTL and an EML. The opposite electrode 170 may include a transmissive conductive layer including a transmissive conductive oxide, such as ITO, In₂O₃, or IZO. In an embodiment, the pixel electrode 150 is used as an anode, and the opposite electrode 170 is used as a cathode. Alternatively, the polarities of the pixel electrode 150 and the opposite electrode 170 may be reversed.

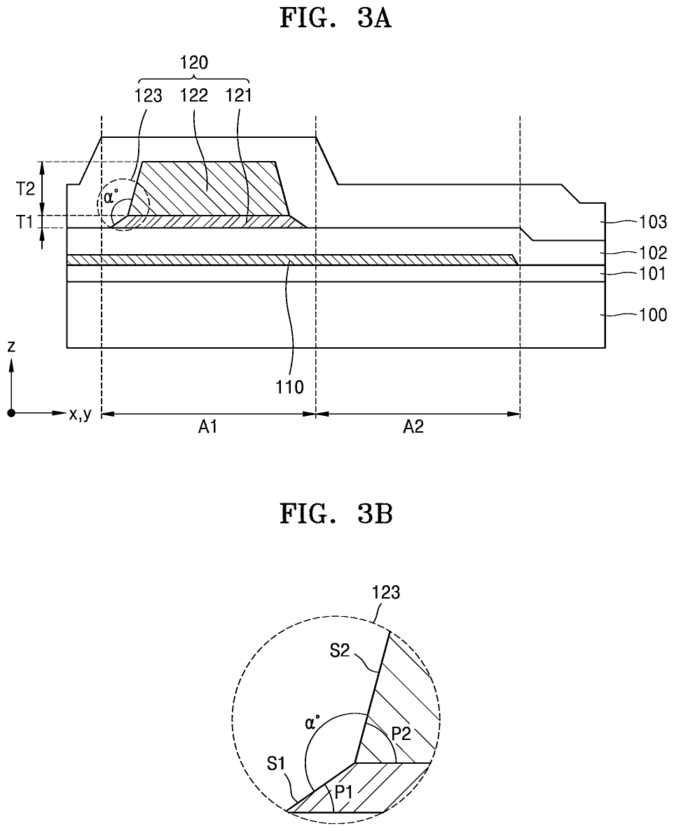

FIG. 3A is a schematic cross-sectional view of the display device before a through hole is formed therein, according to an embodiment, and FIG. 3B is an enlarged view of the encircled portion of FIG. 3A.

In an embodiment, as illustrated in FIG. 3A, the gate layer 120 may include a first layer 121 disposed on the gate insulating layer 102 and including a first metal, and a second layer 122 disposed on the first layer 121 and including a second metal. In such an embodiment, the gate layer 120 may have a multilayer structure including the first layer 121 and the second layer 122. Even when the second layer 122 is etched by a buffered oxide etch (BOE) solution, the first layer 121 may remain without being etched by the BOE solution. In order for the second layer 122 to be etched and the first layer 121 to remain without being etched, the first metal of the first layer 121 may be a metal having an etch rate lower than an etch rate of the second metal of the second layer 122.

In an embodiment, as shown in FIG. 3B, an acute angle P1 between a first side surface S1 of the first layer 121 and the upper surface of the substrate 100 may be less than an acute angle P2 between a second side surface S2 of the second layer 122 and the upper surface of the substrate 100.

Both the first side surface S1 of the first layer 121 and the second side surface S2 of the second layer 122 are side surfaces located at a same side of the gate layer 120, and an angle α° between the first side surface S1 of the first layer 121 and the second side surface S2 of the second layer 122 may be equal to or less than 180°. An area 123 formed by the first side surface S1 and the second side surface S2 that meet each other may be formed by the difference in the etch rates of the first metal and the second metal, and may be formed when the angle α° between the first side surface S1 of the first layer 121 and the second side surface S2 of the second layer 122 is less than 180°.

Hereinafter, the etch rate as used herein refers to an etch rate when an etching process is performed with a same solution (e.g., BOE solution, etc.) under same conditions.

In an embodiment, when the gate layer 120 is patterned along a preset shape, the acute angle P2 between the second side surface S2 of the second layer 122 and the upper surface of the substrate 100 may be relatively large due to the high etch rate of the second metal. In such an embodiment, the acute angle P1 between the first side surface S1 of the first layer 121 and the upper surface of the substrate 100 may be relatively small due to the low etch rate of the first metal.

Due to the difference of the etch rates of the first metal and the second metal, the acute angle P1 between the first side surface S1 of the first layer 121 and the upper surface of the substrate 100 may be less than the acute angle P2 between the second side surface S2 of the second layer 122 and the upper surface of the substrate 100.

In an embodiment, as described above, the gate layer 120 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), molybdenum (Mo), titanium (Ti), tungsten (W), and copper (Cu). In such an embodiment, the first metal may include at least one metal selected from the metals described above, and the etch rate of the first metal may be lower than the etch rate of the second metal including at least one other metal selected from the metals described above.

In an embodiment, for example, the first metal may include titanium (Ti), and the second metal may include aluminum (Al). Titanium (Ti) is a metal that is mainly used for the barrier layer, and the etch rate of titanium (Ti) may be lower than the etch rate of aluminum (Al) under the same conditions. In such an embodiment, when the etching process is performed with a same BOE solution under same conditions, the etch rate of titanium (Ti) is lower than the etch rate of aluminum (Al). In such an embodiment, the structural characteristics of the gate layer 120 of the display device appear due to the difference in the etch rates of the first metal and the second metal.

Here, the same conditions may mean that the environmental conditions (temperature, humidity, atmospheric pressure, etc.) under which the etching process for the first metal is performed are the same as the environmental conditions under which the etching process for the second metal is performed.

As such, due to the characteristics of the angle between the first side surface S1 and the second side surface S2, the display device according to an embodiment does not include an area protruding outward from the surface of the gate layer 120. Accordingly, the roughness of the side surface of the gate layer 120 of the display device according to an embodiment is substantially reduced, compared to the other cases. A comparative example and detailed features of the embodiment will be described below.

A thickness T1 of the first layer 121 may be less than a thickness T2 of the second layer 122. In an embodiment, the thickness T1 of the first layer 121 may be in a range of about 100 angstroms (Å) to about 500 Å, e.g., about 300 Å. in such an embodiment, the thickness T2 of the second layer 122 may be in a range of about 1,000 Å to about 5,000 Å, e.g., about 3,000 Å.

In such an embodiment where the etch rate of the first metal of the first layer 121 is lower than the etch rate of the second metal of the second layer 122, the thickness T1 of the first layer 121 may be less than the thickness T2 of the second layer 122, such that the cost and time for forming the first layer 121 may be reduced.

As illustrated in FIG. 3A, the substrate 100 may include a first area A1 in which the gate layer 120 is located, and a second area A2 in which the semiconductor layer 110 is located among areas other than the first area A1. In an embodiment, the interlayer insulating layer 103 may be formed along the shapes of the semiconductor layer 110 and the gate layer 120. That is, the interlayer insulating layer 103 may be deposited in the first area A1 along the shape of the gate layer 120. Accordingly, the shape of the upper surface of the interlayer insulating layer 103 in the first area A1 may correspond to the shape of the upper surface of the gate layer 120.

In an embodiment, the interlayer insulating layer 103 may be formed in the second area A2 along the shape of the step formed between the buffer layer 101 and the semiconductor layer 110. That is, the interlayer insulating layer 103 may be deposited in the second area A2 along the shape of the step formed between the buffer layer 101 and the semiconductor layer 110. Accordingly, the shape of the upper surface of the interlayer insulating layer 103 in the second area A2 may correspond to the shape of the step.

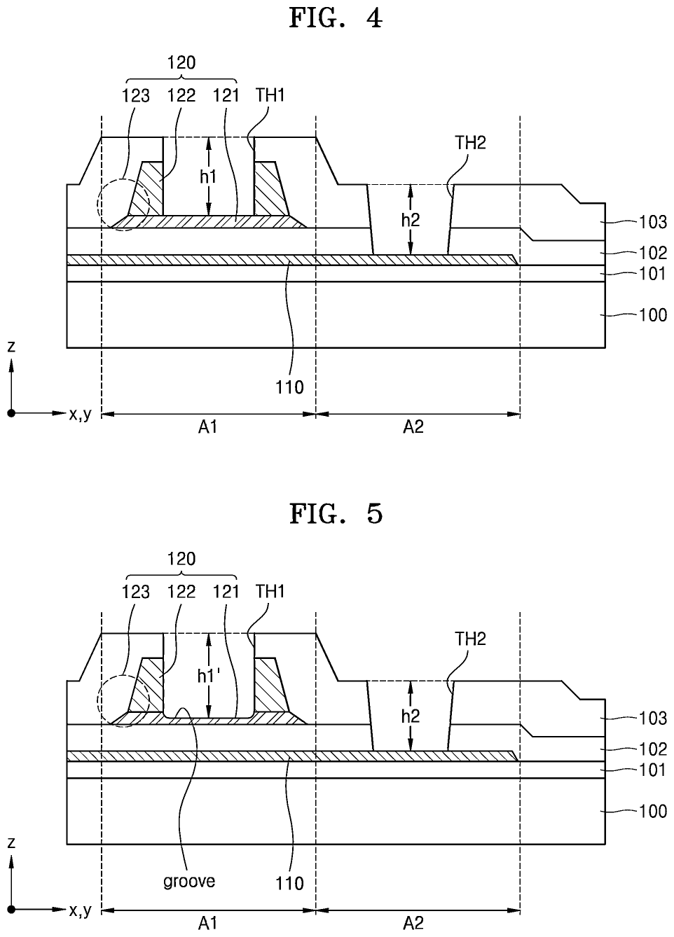

FIG. 4 is a schematic cross-sectional view of the display device of FIG. 3A when a through hole is formed therein. In the following description of FIG. 4, any repetitive detailed descriptions of the same or like elements as those described above are omitted.

In an embodiment, as illustrated in FIG. 4, the substrate 100 may include the first area A1 in which the gate layer 120 is located, and the second area A2 in which the semiconductor layer 110 is located among areas other than the first area A1. In such an embodiment, a first through hole TH1 may be located in the first area A1, and a second through hole TH2 may be located in the second area A2.

The first through hole TH1 may be defined or formed through the second layer 122 in a direction perpendicular to the upper surface of the first layer 121. The first through hole TH1 may be defined or formed through the interlayer insulating layer 103 and the second layer 122. The second through hole TH2 may be defined or formed through the interlayer insulating layer 103 and the gate insulating layer 102.

The first through hole TH1 may have a first depth h1. The first depth h1 may be equal to or greater than the sum of the thickness of the interlayer insulating layer 103 and the thickness of the second layer 122 in the first area A1. A case where the first depth h1 is greater than the sum of the thickness of the interlayer insulating layer 103 and the thickness of the second layer 122 may be a case where a portion of the first layer 121 is removed by etching or the like, as illustrated in FIG. 5.

The second through hole TH2 may have a second depth h2. The second depth h2 may be equal to or greater than the sum of the thickness of the interlayer insulating layer 103 and the thickness of the gate insulating layer 102 in the second area A2. A case where the second depth h2 is greater than the sum of the thickness of the interlayer insulating layer 103 and the thickness of the gate insulating layer 102 may be a case where a portion of the semiconductor layer 110 is removed by etching or the like.

Because the first depth h1 and the second depth h2 include the thickness of the interlayer insulating layer 103 in common, the ratio of the first depth h1 to the second depth h2 may vary depending on the thickness of the second layer 122 and the thickness of the gate insulating layer 102. In an embodiment where the thickness of the gate insulating layer 102 is greater than the thickness of the second layer 122, the first depth h1 may be less than the second depth h2. In an embodiment where the thickness of the second layer 122 is greater than the thickness of the gate insulating layer 102, the first depth h1 may be greater than the second depth h2.

As illustrated in FIG. 2, the display device according to an embodiment may further include a first conductive layer 130 disposed on the interlayer insulating layer 103 and connected to the first layer 121 through the first through hole TH1. The first conductive layer 130 may be connected to the semiconductor layer 110 through the second through hole TH2. That is, the first conductive layer 130 may be connected to the first layer 121 and/or the semiconductor layer 110 through the first through hole TH1 and/or the second through hole TH2. Also, the upper surface of the first layer 121 may be in direct contact with the first conductive layer 130 through the first through hole TH1. The upper surface of the semiconductor layer 110 may be in direct contact with the first conductive layer 130 through the second through hole TH2.

FIG. 5 is a schematic cross-sectional view of the display device of FIG. 4 when a groove is formed therein.

In an embodiment, as illustrated in FIG. 5, the first layer 121 may further include a groove corresponding to the first through hole TH1. In such an embodiment, the first conductive layer 130 may be connected to the first layer 121 through the first through hole TH1 and the groove. In such an embodiment, the first conductive layer 130 may be disposed on the interlayer insulating layer 103, may fill the first through hole TH1 and the groove, and may be connected to the first layer 121 through the first through hole TH1 and the groove, which are filled with the first conductive layer 130. Also, the upper surface of the first layer 121 may be in direct contact with the first conductive layer 130 through the first through hole TH1 and the groove.

In such an embodiment, because the first layer 121 includes the first metal having a low etch rate, the first layer 121 may include only the groove without being penetrated.

The first through hole TH1 and the groove may have a first depth h1′. The first depth h1′ may be equal to the sum of the thickness of the insulating interlayer, the thickness of the second layer 122, and the depth of the groove in the first area A1.

The second through hole TH2 may have a second depth h2. The second depth h2 may be equal to or greater than the sum of the thickness of the interlayer insulating layer 103 and the thickness of the gate insulating layer 102 in the second area A2. A case where the second depth h2 is greater than the sum of the thickness of the interlayer insulating layer 103 and the thickness of the gate insulating layer 102 may be a case where a portion of the semiconductor layer 110 is removed by etching or the like.

Because the first depth h1′ and the second depth h2 include the thickness of the interlayer insulating layer 103 in common, the ratio of the first depth h1′ to the second depth h2 may vary depending on the thickness of the second layer 122 and the thickness of the gate insulating layer 102. In an embodiment where the thickness of the gate insulating layer 102 is greater than the thickness of the second layer 122, the first depth h1′ may be less than the second depth h2. In an embodiment where the thickness of the second layer 122 is greater than the thickness of the gate insulating layer 102, the first depth h1′ may be greater than the second depth h2.

Hereinafter, a method of manufacturing a display device, according to an embodiment, will be described in detail.

In the following description of the method of manufacturing a display device, according to the embodiment, any repetitive detailed descriptions of the same or like elements as those of the display device described above are omitted.

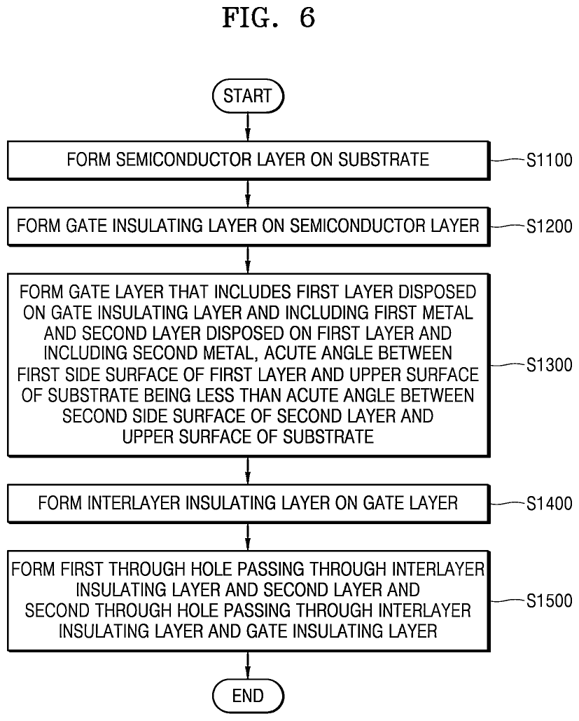

FIG. 6 is a flowchart of a method of manufacturing a display device, according to an embodiment.

As illustrated in FIG. 6, the method of manufacturing a display device (hereinafter, referred to as the manufacturing method), according to an embodiment, may include forming (or providing) a semiconductor layer 110 on a substrate 100 (S1100).

The forming of the semiconductor layer 110 (S1100) may include preparing the substrate 100 on which a buffer layer 101 is formed, and forming (or providing) the semiconductor layer 110 on the buffer layer 101 corresponding to a display area.

The buffer layer 101 may be formed by, for example, deposition, such as CVD, thermochemical vapor deposition (TCVD), or plasma-enhanced chemical vapor deposition (PECVD). The semiconductor layer 110 may be formed by a deposition process using the deposition described above, a photolithography process, an etching process, and an impurity doping process.

The manufacturing method according to an embodiment may further include, after forming the semiconductor layer 110, forming (or providing) a gate insulating layer 102 on the semiconductor layer 110 (S1200). The gate insulating layer 102 may be formed by, for example, the deposition described above.

The manufacturing method according to an embodiment may further include, after forming the gate insulating layer 102, forming (or providing) a gate layer 120 that includes a first layer 121 disposed on the gate insulating layer 102 and including a first metal, and a second layer 122 disposed on the first layer 121 and including a second metal (S1300).

As described above, due to the difference in the etch rates of the first metal and the second metal, the gate layer 120 may be formed to have a structure in which the acute angle P1 between the first side surface S1 of the first layer 121 and the upper surface of the substrate 100 is less than the acute angle P2 between the second side surface S2 of the second layer 122 and the upper surface of the substrate 100.

As illustrated in FIG. 6, the manufacturing method according to an embodiment may further include, after forming the gate layer 120, forming (or providing) an interlayer insulating layer 103 on the gate layer 120 (S1400).

The interlayer insulating layer 103 may be formed by, for example, deposition, such as CVD, TCVD, or PECVD.

As illustrated in FIG. 6, the manufacturing method according to an embodiment may further include, after forming the interlayer insulating layer 103, forming a first through hole TH1 through the interlayer insulating layer 103 and the second layer 122 and forming a second through hole TH2 through the interlayer insulating layer 103 and the gate insulating layer 102 (S1500).

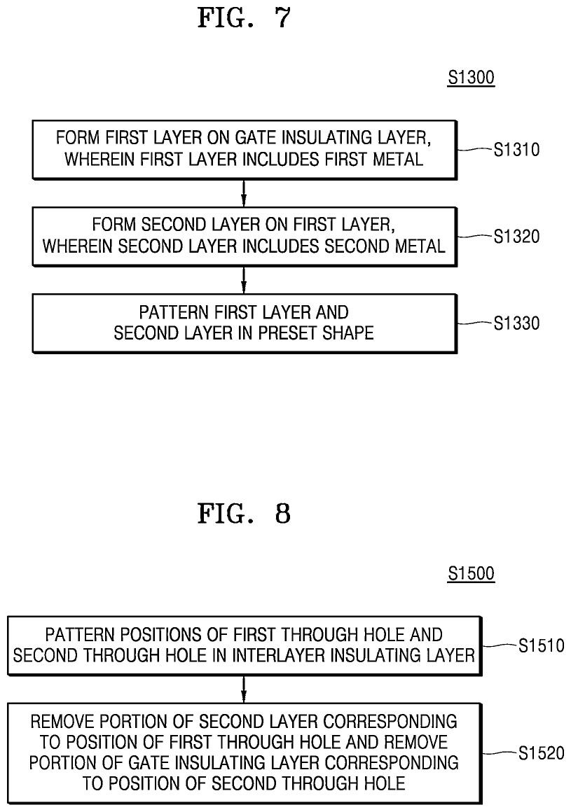

FIG. 7 is a schematic flowchart of the process of forming the gate layer in the manufacturing method of FIG. 6.

As illustrated in FIG. 7, the forming of the gate layer 120 (S1300) may include forming the first layer 121 on the gate insulating layer 102, where the first layer 121 includes the first metal (S1310), forming the second layer 122 on the first layer 121, where the second layer 122 includes the second metal (S1320), and patterning the first layer 121 and the second layer 122 in a preset shape (S1330).

The forming of the first layer 121 (S1310) may include forming the first layer 121 by, for example, the deposition (e.g., CVD, TCVD, or PECVD) using the first metal. The forming of the second layer 122 (S1320) may include forming the second layer 122 by, for example, the deposition using the second metal.

In an embodiment, as described above, the gate layer 120 may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), titanium (Ti), tungsten (W), and copper (Cu). In such an embodiment, the first metal may include at least one metal selected from the metals described above, and the etch rate of the first metal may be lower than the etch rate of the second metal including at least one other metal selected from the metals described above.

In an embodiment, for example, the first metal may include titanium (Ti), and the second metal may include aluminum (Al). Titanium (Ti) is a metal that is mainly used for the barrier layer, and the etch rate of titanium (Ti) may be lower than the etch rate of aluminum (Al) under same conditions. In such an embodiment, when the etching process is performed with a same BOE solution under same conditions, the etch rate of titanium (Ti) is lower than the etch rate of aluminum (Al). As such, the structural characteristics of the gate layer 120 of the display device appear due to the difference in the etch rates of the first metal and the second metal.

Herein, the same conditions may mean that the environmental conditions (temperature, humidity, atmospheric pressure, etc.) under which the etching process for the first metal is performed are the same as the environmental conditions under which the etching process for the second metal is performed.

The patterning in the preset shape (S1330) may be performed by an etching process and a photolithography process using a mask. The photolithography process may use a negative photoresist or a positive photoresist.

The mask may be divided into a transmissive area that transmits light and a blocking area that blocks light, according to transmittance. Alternatively, a halftone mask may be used. The type of mask may be variously changed. The scope of the disclosure is not limited by the type of mask.

In the patterning in the preset shape (S1330), after a negative photoresist is applied onto the first layer 121 and the second layer 122, when the photoresist is exposed and developed through a mask, a first portion of the photoresist corresponding to the transmissive area of the mask is not removed and remains thick, and a second portion of the photoresist corresponding to the blocking area of the mask is not exposed and is thus removed. When the first layer 121 and the second layer 122 are etched based on a photoresist pattern thus formed, a gate electrode may be formed in an area corresponding to the first portion.

FIG. 8 is a schematic flowchart of the process of forming the through hole in the manufacturing method of FIG. 6.

As illustrated in FIG. 8, the forming of the first through hole TH1 and the second through hole TH2 (S1500) may include removing portions of the interlayer insulating layer 103 corresponding to the positions of the first through hole TH1 and the second through hole TH2 (S1510), removing a portion of the second layer 122 corresponding to the position of the first through hole TH1 (S1520), and removing a portion of the gate insulating layer 102 corresponding to the position of the second through hole TH2. In such an embodiment, the photolithography process and the etching process described above may be used to form the first through hole TH1 and the second through hole TH2. The photolithography process may use a negative photoresist or a positive photoresist.

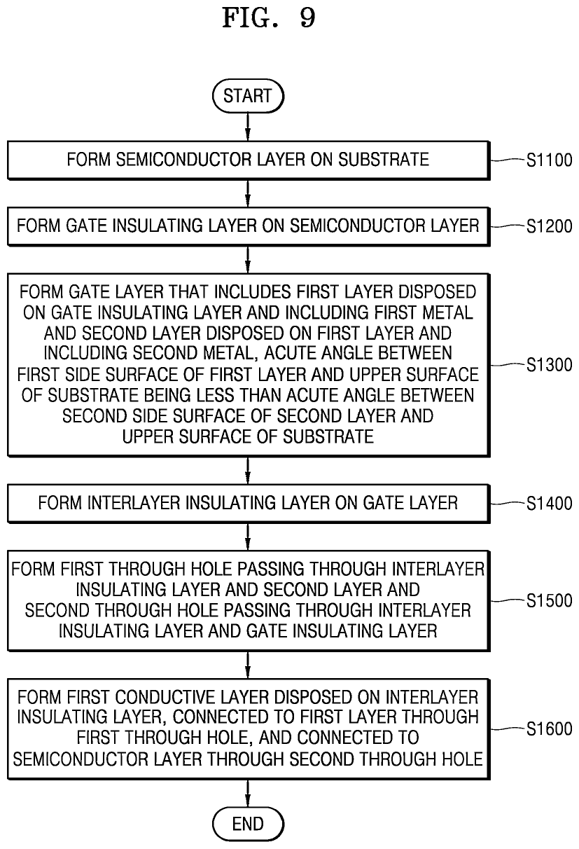

FIG. 9 is a flowchart of a process of forming a first conductive layer, which is added to the manufacturing method of FIG. 6.

As illustrated in FIG. 9, the manufacturing method according to an embodiment may further include, after forming the first through hole TH1 and the second through hole TH2, forming a first conductive layer 130 on the interlayer insulating layer 103, to be connected to the first layer 121 through the first through hole TH1, and to be connected to the semiconductor layer 110 through the second through hole TH2 (S1600).

In an embodiment, as described above, the first conductive layer 130 may be located on the interlayer insulating layer 103 and may be connected to the first layer 121 through the first through hole TH1. That is, the first conductive layer 130 formed in operation S1600 may be in direct contact with the upper surface of the first layer 121.

Alternatively, in the forming of the first through hole TH1 and the second through hole TH2 (S1500), a groove may be further formed in the upper surface of the first layer 121. Because the first through hole TH1 and the second through hole TH2 have to be formed at the same time or through a same process, the groove may be further formed in the upper surface of the first layer 121 to etch the second through hole TH2 to a desired depth. In such an embodiment, because the first layer 121 includes the first metal having a low etch rate, the first layer 121 may not be penetrated and may include only the groove.

Through the forming of the first conductive layer 130 (S1600), the first conductive layer 130 may be connected to the semiconductor layer 110 through the second through hole TH2. That is, the first conductive layer 130 may be connected to the first layer 121 and/or the semiconductor layer 110 through the first through hole TH1 and/or the second through hole TH2. Also, the upper surface of the first layer 121 may directly contact the first conductive layer 130 through the first through hole TH1 and the groove. The upper surface of the semiconductor layer 110 may be in direct contact with the first conductive layer 130 through the second through hole TH2.

Hereinafter, an embodiment and a comparative example will be described in detail based on the descriptions given above. In the following description of the embodiment and the comparative example, any repetitive detailed descriptions of the same or like elements as those described above are omitted.

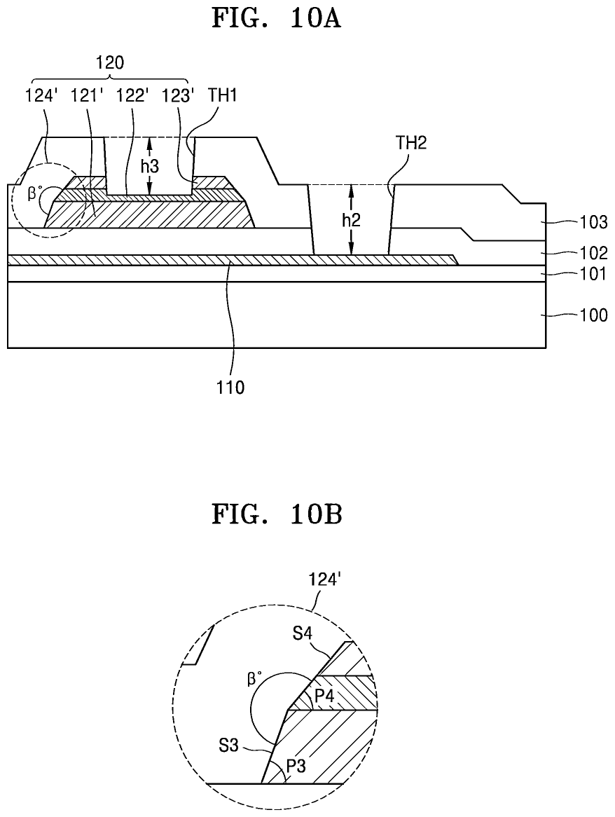

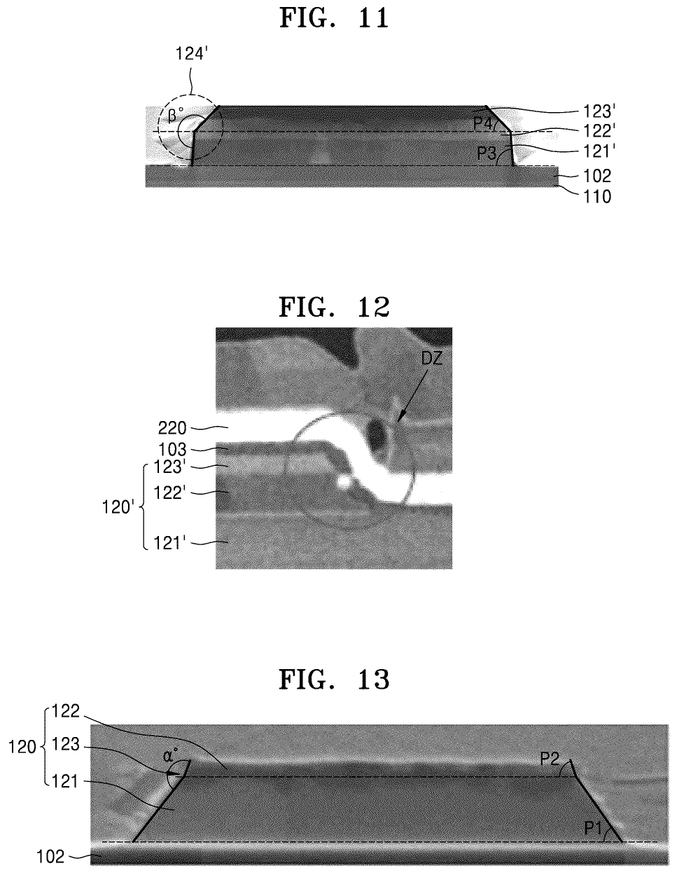

FIG. 10A is a schematic cross-sectional view of a display device according to a comparative example, FIG. 10B is an enlarged view of the encircled portion of FIG. 10A, and FIG. 11 is a photograph showing a cross-section of a gate layer in the display device according to the comparative example.

As illustrated in FIGS. 10 and 11, in a comparative example, the gate layer 120′ may have a multilayer structure including three layers. The gate layer 120′ may include a first layer 121′ disposed on the gate insulating layer 102, a second layer 122′ disposed on the first layer 121′, and a third layer 123′ disposed on the second layer 122′. The first layer 121′ may include a first metal, and the second layer 122′ and the third layer 123′ may each include a second metal.

The gate layer 120′ may include the second layer 122′ and/or the third layer 123′ as a barrier layer. Accordingly, the second metal may be a metal having a relatively low etch rate. That is, the second layer 122′ and/or the third layer 123′ may not be etched by the BOE solution, or a portion of the second layer 122′ may remain even when the second layer 122′ is etched.

An acute angle P3 between a first side surface S3 of the first layer 121′ and the upper surface of the substrate 100 may be greater than an acute angle P4 between a second side surface S4 of the second layer 122′ and the upper surface of the substrate 100.

Both the first side surface S3 of the first layer 121′ and the second side surface S4 of the second layer 122′ are located at a same side of the gate layer 120′, and an angle β° between the first side surface S3 of the first layer 121′ and the second side surface S4 of the second layer 122′ may be greater than 180°.

An area 123′ formed by the first side surface S3 and the second side surface S4 that meet each other may be formed by the difference in the etch rates of the first metal and the second metal.

In the comparative example, when the gate layer 120′ is patterned along a preset shape, the acute angle P3 between the first side surface S3 of the first layer 121′ and the upper surface of the substrate 100 may be relatively large due to the high etch rate of the first metal. However, the acute angle P4 between the second side surface S4 of the second layer 122′ and the upper surface of the substrate 100 may be relatively small due to the low etch rate of the second metal. Due to the difference of the etch rates of the first metal and the second metal, the acute angle P3 between the first side surface S3 of the first layer 121′ and the upper surface of the substrate 100 may be greater than the acute angle P4 between the second side surface S4 of the second layer 122′ and the upper surface of the substrate 100.

As described above, the gate layer 120′ may include at least one metal selected from aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), molybdenum (Mo), titanium (Ti), tungsten (W), and copper (Cu). In this case, the first metal may include at least one metal selected from the metals described above, and the etch rate of the first metal may be lower than the etch rate of the second metal including at least one other metal selected from the metals described above.

For example, the gate layer 120′ according to the comparative example may have a multilayer structure of Ti/TiN/Al. That is, the first metal may include aluminum (Al), and the second metal may include titanium (Ti). The first layer 121′ may be a layer including aluminum (Al), the second layer 122′ may be a layer including titanium nitride (TiN), and the third layer 123′ may be a layer including titanium (Ti).

As such, due to the characteristics of the angle β° between the first side surface S3 and the second side surface S4, the display device according to the comparative example includes an area protruding outward from the surface of the gate layer 120′. Accordingly, the roughness of the side surface of the gate layer 120′ of the display device according to the comparative example is much higher than the roughness of the side surface of the gate layer 120 of the display device according to an embodiment.

FIG. 12 is a photograph showing an area in which a short circuit occurs in the cross-section of the display device according to the comparative example, and FIG. 13 is a photograph showing the cross-section of the gate layer in the display device according to an embodiment.

As illustrated in FIG. 12, the display device according to the comparative example may include the gate layer 120′ having the multilayer structure of the first layer 121′, the second layer 122′, and the third layer 123′. As described above, the area formed by the first side surface S3 and the second side surface S4 that meet each other protrudes toward the outside of the gate layer 120′, and the gate layer 120′ may be in contact with another conductive layer 220.

Accordingly, a short circuit occurs due to the contact between the gate layer 120′ and the other conductive layer 220, and the occurrence of the short circuit is confirmed in an area DZ illustrated in FIG. 12. The short circuit adversely affects voltage characteristics of a capacitor formed by the gate layer 120′ and the other conductive layer 220.

On the other hand, as illustrated in FIG. 13, the display device according to an embodiment does not include an area protruding outward from the gate layer 120. Accordingly, the roughness of the side surface of the gate layer 120 of the display device according to the embodiment is significantly reduced, compared to the comparative example, and the reduced roughness of the side surface of the gate layer 120 may substantially or effectively reduce the occurrence rate of the short circuit between the gate layer 120 and another conductive layer (not illustrated).

According to one or more embodiments, the display device including the gate layer with a side surface having no protrusion portion and the method of manufacturing the display device may be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a semiconductor layer disposed on the substrate;
a gate insulating layer disposed on the semiconductor layer;
a gate layer comprising a first layer disposed on the gate insulating layer and including a first metal, and a second layer disposed on the first layer and including a second metal, wherein a first through hole is defined through the second layer in a direction perpendicular to an upper surface of the first layer; and
an interlayer insulating layer disposed on the gate layer.

2. The display device of claim 1, wherein an acute angle between a first side surface of the first layer and an upper surface of the substrate is less than an acute angle between a second side surface of the second layer and the upper surface of the substrate,
wherein the first side surface and the second side surface correspond to a same side surface of the gate layer.

3. The display device of claim 1, wherein
the first through hole is defined through the interlayer insulating layer and the second layer together, and
the display device further comprises a first conductive layer disposed on the interlayer insulating layer and connected to the first layer through the first through hole.

4. The display device of claim 3, wherein
a groove is defined in the first layer to correspond to the first through hole, and
the first conductive layer fills the groove.

5. The display device of claim 2, wherein an angle between the first side surface and the second side surface is less than about 180°.

6. The display device of claim 3, wherein the first conductive layer is connected to the semiconductor layer through a second through hole defined through the interlayer insulating layer and the gate insulating layer.

7. The display device of claim 6, wherein
the substrate comprises a first area, in which the gate layer is located, and a second area, in which the semiconductor layer is located, among areas other than the first area,
the first through hole is located in the first area, and
the second through hole is located in the second area.

8. The display device of claim 1, wherein
the first metal includes titanium (Ti), and
the second metal includes aluminum (Al).

9. The display device of claim 1, wherein an etch rate of the first metal is lower than an etch rate of the second metal under a same condition.

10. The display device of claim 3, wherein the upper surface of the first layer is in direct contact with the first conductive layer through the first through hole.

11. A method of manufacturing a display device, the method comprising:
providing a semiconductor layer on a substrate;
providing a gate insulating layer on the semiconductor layer;
providing a gate layer comprising a first layer disposed on the gate insulating layer and including a first metal, and a second layer disposed on the first layer and including a second metal;
providing an interlayer insulating layer on the gate layer; and
forming a first through hole through the interlayer insulating layer and the second layer, and forming a second through hole through the interlayer insulating layer and the gate insulating layer.

12. The method of claim 11, wherein the providing the gate layer comprises forming the gate layer in a way such that an acute angle between a first side surface of the first layer and an upper surface of the substrate is less than an acute angle between a second side surface of the second layer and the upper surface of the substrate.

13. The method of claim 11, further comprising:
providing a first conductive layer on the interlayer insulating layer, to be connected to the first layer through the first through hole, and to be connected to the semiconductor layer through the second through hole.

14. The method of claim 12, wherein
the forming the first through hole and the second through hole comprises forming a groove corresponding to the first through hole in the first layer, and
the providing the first conductive layer comprises providing the first conductive layer to be connected to the first layer through the first through hole and the groove.

15. The method of claim 12, wherein the providing the first conductive layer comprises providing the first conductive layer in a way such that an upper surface of the first layer is in direct contact with the first conductive layer through the first through hole.

16. The method of claim 11, wherein the providing the gate layer comprises:
forming the first layer on the gate insulating layer, wherein the first layer includes the first metal;
forming the second layer on the first layer, wherein the second layer includes the second metal; and
patterning the first layer and the second layer in a preset shape.

17. The method of claim 11, wherein the forming the first through hole and the second through hole comprises:
removing portions of the interlayer insulating layer corresponding to a position of the first through hole and a position of the second through hole, respectively;
removing a portion of the second layer corresponding to the position of the first through hole; and
removing a portion of the gate insulating layer corresponding to the position of the second through hole.

18. The method of claim 12, wherein an etch rate of the first metal is lower than an etch rate of the second metal under a same condition.

19. The method of claim 12, wherein
the first metal includes titanium (Ti), and
the second metal includes aluminum (Al).
